(19) United States
(12) Patent Application Publication
(10) Pub. No.: US 2010/0084969 A1
(43) Pub. Date: Apr. 8, 2010

(54) ORGANIC LIGHT EMITTING DISPLAY AND METHOD OF MANUFACTURING THE SAME

(76) Inventors: Jun-Ho Choi, Yongin-si (KR); Jin-Koo Chung, Suwon-si (KR)

Correspondence Address: Innovation Counsel LLP, 21771 Stevens Creek Blvd, Ste. 200A, Cupertino, CA, 95014, US

(21) Appl. No.: 12/572,223

(22) Filed: Oct. 1, 2009

(30) Foreign Application Priority Data
Oct. 2, 2008 (KR) 10-2008-0097202

(51) Int. Cl. H01L 51/50; H01L 21/02

(52) U.S. Cl. 313/504; 438/29; 257/E21.002

(57) ABSTRACT

An organic light emitting display (OLED) includes a substrate, a first electrode, an organic light emitting layer, and a second electrode, which are sequentially formed on the substrate. The second electrode is formed by an imprint method to have different thickness in different regions thereof. Thus, an amount of light exiting the OLED increases because the second electrode is thinner in an area where the light exits, and an electrical resistance of the second electrode is reduced because the second electrode is thicker in the peripheral area.

### CROSS-REFERENCE TO RELATED APPLICATION

This application claims priority to Korean Patent Application No. 2008-97202 filed on Oct. 2, 2008, the contents of which are herein incorporated by reference in their entirety.

### BACKGROUND OF THE INVENTION

1. Field of the Invention

The present invention relates to an organic light emitting display having improved display quality and a method of manufacturing the organic light emitting display.

2. Description of the Related Art

Recently, organic light emitting display (OLED) devices have been the subject of steadily increasing attention in the field of flat panel displays. In general, an OLED includes an organic light emitting layer, a cathode electrode arranged on the organic light emitting layer, and an anode electrode arranged under the organic light emitting layer. An OLED displays images with light emitted from an organic light emitting layer using a current generated by voltage applied to the cathode electrode and the anode electrode.

OLEDs are classified into top-emission type OLEDs and bottom-emission type OLEDs. In a top-emission type OLED, light emitted from the organic light emitting layer exits through the cathode electrode. In the bottom-emission type OLED, light emitted from the organic light emitting layer is reflected by the cathode electrode and exits through the anode electrode.

In a top-emission OLED, it is desirable to decrease a thickness of the cathode electrode to maximize the amount of light that OLED emits to improve the display quality. However, as the cathode electrode becomes thinner, electrical resistance of the cathode electrode increases, and the electrical conductivity of the cathode electrode decreases. The decreased amount of electrical current provided to the organic light emitting layer causes deterioration of the display quality of the OLED.

### SUMMARY OF THE INVENTION

An exemplary embodiment of the present invention provides an organic light emitting display having improved display quality.

Another exemplary embodiment of the present invention provides a method of manufacturing the organic light emitting display.

In an exemplary embodiment of the present invention, an organic light emitting display includes a substrate having a plurality of pixel areas and a peripheral area surrounding each pixel area, a first electrode arranged on the substrate in each pixel area, a bank pattern arranged on the first electrode and provided with openings corresponding to each pixel area, and an organic light emitting layer filled in each opening and arranged on the first electrode. The organic light emitting display further includes a second electrode arranged on the organic light emitting layer, the second electrode layer in the peripheral area is thicker than the second electrode layer in the pixel areas.

In another exemplary embodiment of the present invention, a method of manufacturing an organic light emitting display is provided as follows. A substrate having a plurality of pixel areas and a peripheral area defined as an area between two adjacent pixel areas is prepared. A first electrode is formed on the substrate in each pixel area, and a bank pattern provided with openings corresponding to each pixel area is formed on the first electrode. After forming the bank pattern, an organic light emitting layer is formed in each opening and a second electrode is formed on the organic light emitting layer.

The second electrode is formed by forming a first conductive layer on the organic light emitting layer and forming a second conductive layer on the first conductive layer by an imprint method.

According to the above, the second electrode is formed by an imprint method to have different thickness in different regions. Thus, the amount of light emitted by the display is maximized, and the electrical resistance of the second electrode is reduced.

### BRIEF DESCRIPTION OF THE DRAWINGS

The above and other advantages of the present invention will become readily apparent by reference to the following detailed description when considered in conjunction with the accompanying drawings wherein:

FIG. 1 is a plan view showing an exemplary embodiment of an organic light emitting display according to the present invention;

FIG. 2A is a plan view showing a structure of a pixel of an organic light emitting display of FIG. 1;

FIG. 2B is a cross-sectional view taken along a line II-II′ of FIG. 2A;

FIG. 3 is a cross-sectional view taken along a line I-I′ of FIG. 1; and

FIGS. 4 to 7 are cross-sectional views showing a method of forming an organic light emitting display of FIG. 3.

### DESCRIPTION OF THE EMBODIMENTS

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

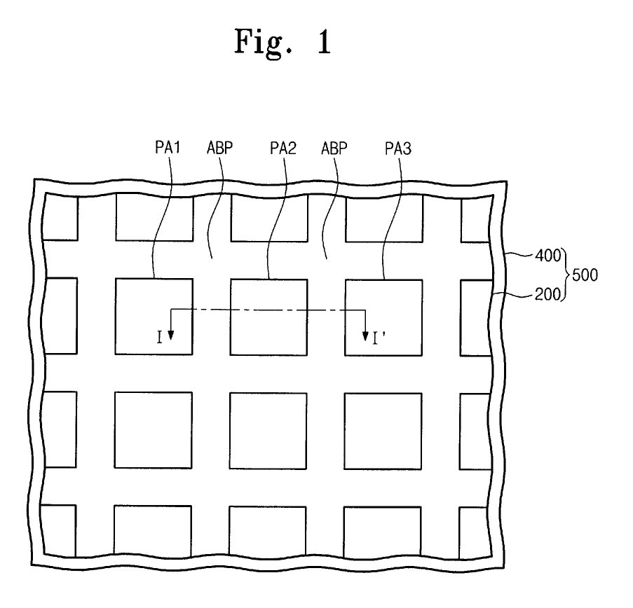

FIG. 1 is a plan view showing an exemplary embodiment of an organic light emitting display according to the present invention.

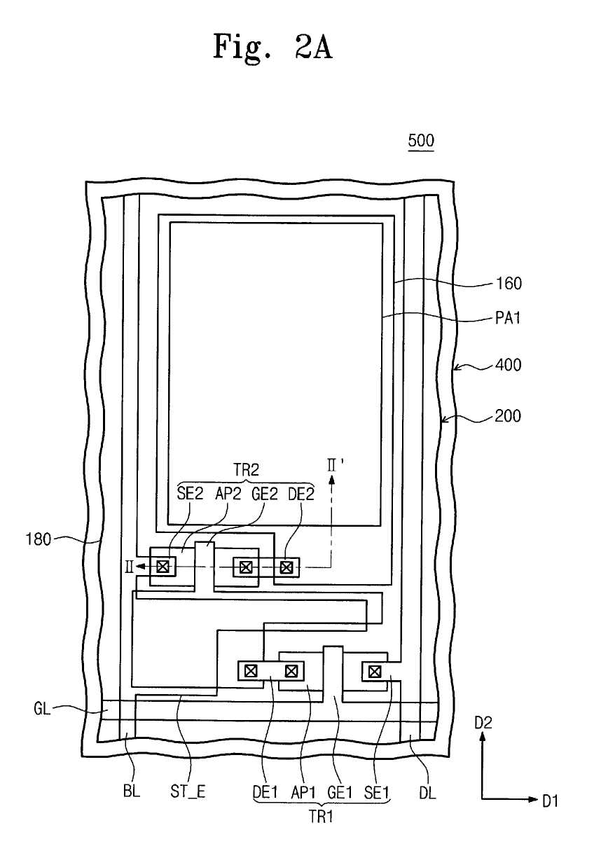

Referring to FIG. 1, an organic light emitting display (OLED) 500 includes a display substrate 200 and an cover substrate 400. The display substrate 200 includes a first electrode 160 (shown in FIG. 2B), a second electrode 180 (shown in FIG. 2B), and an organic light emitting layer EL (shown in FIG. 2B). The organic light emitting layer EL emits light using a current generated by voltage applied to the first and second electrodes 160 and 180. The OLED 500 displays images using the light emitted from the organic light emitting layer EL.

The display substrate 200 includes a plurality of pixel areas, including a first pixel area PA1, a second pixel area PA2, a third pixel area PA3, and so forth. In a plan view, the pixel areas are arranged in a matrix configuration along a row direction and a column direction that is substantially perpendicular to the row direction. The display substrate 200 includes a pixel which generates light in each pixel area. Detailed description of the structure of the pixel is described with reference to FIGS. 2A and 2B.

The cover substrate 400 is coupled with the display substrate 200 and faces the display substrate 200. The cover substrate 400 covers the display substrate 200 to prevent the organic light emitting layer EL from being exposed, preventing deterioration of the light emitting function of the organic light emitting layer EL.

FIG. 2A is a plan view showing the structure of a pixel of the organic light emitting display of FIG. 1, and FIG. 2B is a cross-sectional view taken along a line II-IP of FIG. 2A. The structure of the display substrate 200 corresponding to the first pixel area PA1 and a peripheral area ABP (shown in FIG. 1) surrounding the first pixel area PA1 is illustrated in detail in FIG. 2A. Although a reference numeral is not assigned to the peripheral area in FIG. 2A, the area outside of the first pixel area PA1 is regarded as the peripheral area ABP in FIG. 2A.

The OLED 500 includes a plurality of pixels each having the same circuit configuration and function. Thus, only one pixel corresponding to the first pixel area PA1 is illustrated in FIG. 2A, and descriptions of others are omitted.

Referring to FIGS. 2A and 2B, the display substrate 200 includes a substrate 100, a gate line GL, a data line DL, a power supply line BL, a first thin film transistor TR1, a second thin film transistor TR2, a first electrode 160, a second electrode 180, an organic light emitting layer EL, a storage electrode ST_E, and a bank pattern 150.

The gate line GL which transmits a gate signal that turns on the first thin film transistor TR1 is arranged on the substrate 100 and extends in a first direction D1. The data line DL and the power supply line BL are insulated from the gate line GL and extend on the substrate 100 in a second direction D2 that is substantially perpendicular to the first direction D1. The data line DL transmits a data signal and the power supply line BL transmits a power voltage that is used to emit light from the organic light emitting layer EL.

The first thin film transistor TR1 includes a first active pattern AP1, a first source electrode SE1, a first drain electrode DE1, and a first gate electrode GE1. The first thin film transistor TR1 has a structure of a top-gate type thin film transistor, and thus the first gate electrode GE1 is arranged on the first active pattern AP1. The first thin film transistor TR1 is turned on by the gate signal to transmit the data signal to the first drain electrode DE1.

The second thin film transistor TR2 includes a second active pattern AP2, a second source electrode SE2, a second drain electrode DE2, and a second gate electrode GE2. Similarly to the first thin film transistor TR1, the second thin film transistor TR2 has the structure of a top-gate type thin film transistor. More particularly, the second active pattern AP2 is arranged on the substrate 100 and the second gate electrode GE2 is arranged on the second active pattern AP2. A first insulating layer 110 and a second insulating layer 120 are arranged on the second gate electrode GE2 and the second active pattern AP2. The second source electrode SE2 and the second drain electrode DE2 are arranged on the second insulating layer 120. The first and second insulating layers 110 and 120 are partially removed such that the second source electrode SE2 and the second drain electrode DE2 contact the second active pattern AP2. A third insulating layer 130 is arranged on the second source electrode SE2 and the second drain electrode DE2.

The first drain electrode DE1 is electrically connected to the second gate electrode GE2. Thus, when the first thin film transistor TR1 is turned on, the data signal applied to the first drain electrode DE1 is transmitted to the second gate electrode GE2 to turn on the second thin film transistor TR2.

The second source electrode SE2 branches from the power supply line BL and the second drain electrode DE2 is electrically connected to the first electrode 160. As such, when the second thin film transistor TR2 is turned on, the power voltage transmitted through the power supply line BL is applied to the first electrode 160 through the second drain electrode DE2, and the power voltage may be used to emit light from the organic light emitting layer EL formed on the first electrode 160.

The storage electrode ST_E branches from the power supply line BL and overlaps the second gate electrode GE2 is shown in a plan view. The storage electrode ST_E and the second gate electrode GE2 form a storage capacitor that is used to emit light from the organic light emitting layer EL.

The first electrode 160 is arranged on the third insulating layer 130 corresponding to the first pixel area PA1 and electrically connected to the second drain electrode DE2 through a contact hole formed through the third insulating layer 130. The bank pattern 150 is arranged on the third insulating layer 130 in the peripheral area ABP and a portion of the bank pattern 150 corresponding to the first pixel area PA1 is removed.

The organic light emitting layer EL is arranged on the bank pattern 150 in the peripheral area ABP, and the organic light emitting layer EL is arranged on the first electrode 160 in the first pixel area PA1. The organic light emitting layer EL emits the light using the current provided through the first electrode 160 or the second electrode 180, and the light exits through the cover substrate 400.

In the present exemplary embodiment, the organic light emitting layer EL is formed on the entire surface of the substrate 100. Referring again to FIG. 1, the organic light emitting layer EL is arranged on the substrate 100 to cover the pixel areas PA1, PA2, and PA3 and the peripheral area ABP in a plan view.

The second electrode 180 is arranged on the organic light emitting layer EL. The second electrode 180 may include at least one of aluminum, silver, and magnesium.

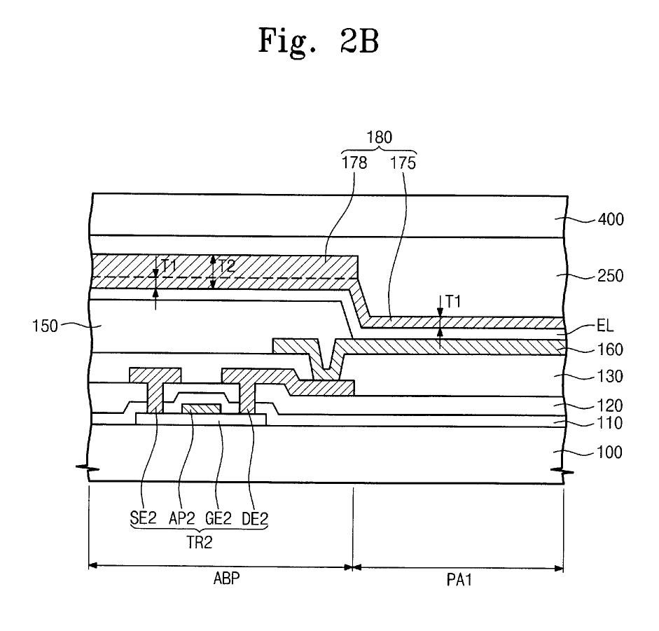

The second electrode 180 includes a first conductive layer 175 arranged on the organic light emitting layer EL and a second conductive layer 178 arranged on the first conductive layer 175 in the peripheral area ABP. The second electrode 180 has a first thickness T1 in the first pixel area PA1 and a second thickness T2 which is thicker than the first thickness T1 in the peripheral area ABP. The first conductive layer 175 and the second conductive layer 178 may comprise the same material. The second conductive layer 178 is transferred onto the first conductive layer 175 by an imprint method and formed on the first conductive layer 175. More detailed descriptions of the structure and function of the second electrode 180 is described with reference to FIG. 3.

A protective layer 250 is arranged on the second electrode 180 to prevent the organic light emitting layer EL from being deteriorated by gas or humidity, thereby preventing deterioration of the light emitting function of the organic light emitting layer EL. The cover substrate 400 is coupled with the display substrate 200 and is arranged on the protective layer 250 to face the display substrate 200.

FIG. 3 is a cross-sectional view taken along the line I-I′ in FIG. 1.

Referring to FIG. 3, the first electrode 160 is arranged on the third insulating layer 130 in each of the first to third pixel areas PA1, PA2, and PA3. The bank pattern 150 is arranged on the third insulating layer 130 in the peripheral area ABP.

The second electrode 180 includes the first conductive layer 175 and the second conductive layer 178 arranged on the first conductive layer 175. The first conductive layer 175 is arranged on the organic light emitting layer EL and has the first thickness T1. Also, the second conductive layer 178 is arranged on the first conductive layer 175 in the peripheral area ABP and has a thickness equal to the difference between the second thickness T2 and the first thickness T1.

In a top-emission type OLED, a light emitted from an organic light emitting layer exits through a second electrode. Thus, a thin second electrode maximizes the amount of light exiting the device. As the second electrode becomes thinner, however, the electrical resistance of the second electrode increases, and lowers its electrical conductivity. As shown in the present exemplary embodiment, when the second electrode 180 has different thicknesses in different regions, the amount of light exiting through the first to third pixel areas PA1, PA2, and PA3 may be maximized by decreasing the thickness of the second electrode 180 in the first to third pixel areas PA1, PA2, and PA3, and the electrical resistance of the second electrode 180 may be reduced by increasing the thickness of the second electrode 180 in the peripheral area ABP.

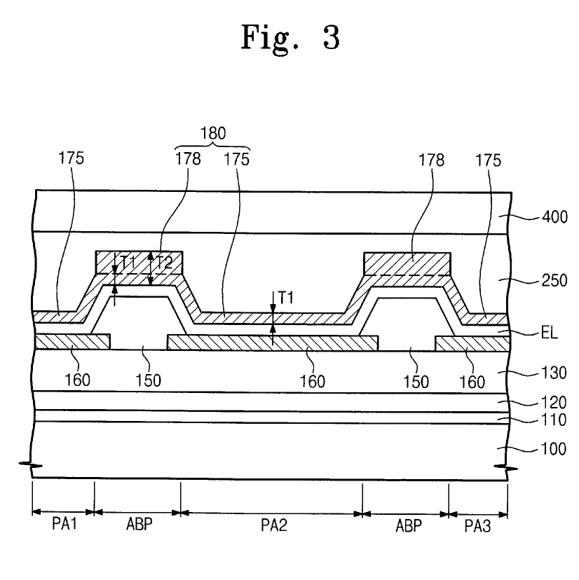

FIGS. 4 to 7 are cross-sectional views showing a method of forming the organic light emitting display of FIG. 3. In FIGS. 4 to 7, the same reference numerals denote the same elements shown in FIGS. 1 to 3, and thus the detailed descriptions of the same elements are omitted.

Referring to FIG. 4, a first insulating layer 110, a second insulating layer 120, and a third insulating layer 130 are sequentially formed on a substrate 100. Although not shown in detail in FIG. 4, a first thin film transistor TR1 (shown in FIG. 1) and a second thin film transistor TR2 (shown in FIG. 1) are formed at the same time the first to third insulating layers 110, 120, and 130 are formed on the substrate 100. A first electrode 160 is formed on the third insulating layer 130 in each of first, second, and third pixel areas PA1, PA2, and PA3.

After forming the first electrode 160, a bank pattern 150 is formed. The bank pattern 150 is formed by forming an insulating layer (not shown) on the third insulating layer 130 to cover the first electrode 160 and patterning the insulating layer to expose the first electrode 160 in each of the first to third pixel areas PA1, PA2, and PA3.

After forming the bank pattern 150, an organic light emitting layer EL is formed, and a first preliminary conductive layer 171 having a first thickness T1 is formed on the organic light emitting layer EL. The first preliminary conductive layer 171 may include at least one of aluminum, silver, and magnesium.

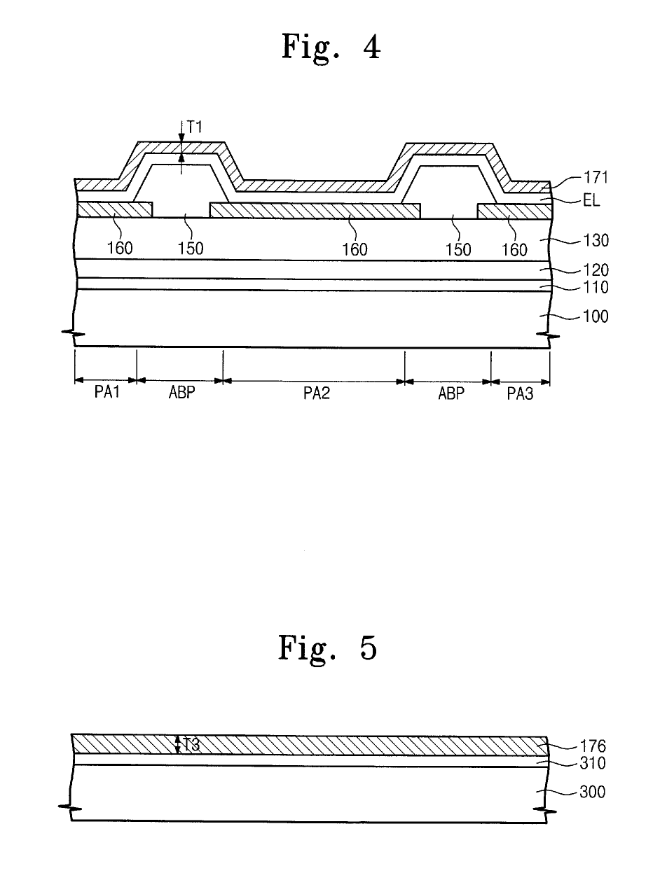

Referring to FIG. 5, a mold 300 is first prepared. Then, a coating layer 310 is formed on a surface of the mold 300, and a second preliminary conductive layer 176 is formed with a third thickness T3 on the coating layer 310. The mold 300 may include a hard material such as glass, and the mold 300 may include a resin that is curable upon exposure to ultraviolet light to impart flexibility depending on the ultraviolet light curing rate of the resin. Preferably, the mold 300 may include a flexible material, such as polyurethane (PUA) and polydimethylsiloxane (PDMS).

The coating layer 310 may include a teflon-based material such as fluorinated ethylene propylene copolymer (FEP). The a cohesive force between the second preliminary conductive layer 176 and the mold 300 is preferably greater than the cohesive force between the coating layer 310 and the second preliminary conductive layer 176. Therefore, when the second preliminary conductive layer 176 is formed on the mold 300, the second preliminary conductive layer 176 may be easily separated from the mold 300 due to the coating layer 310. That is, when the second preliminary conductive layer 176 is transferred onto the first preliminary conductive layer 171 (shown in FIG. 4), the second preliminary conductive layer 176 formed on the coating layer 310 can be easily transferred onto the first preliminary conductive layer 171.

In the present exemplary embodiment, after the second preliminary conductive layer 176 is formed on the mold 300, the coating layer 310 allows the second preliminary conductive layer 176 to easily separate from the mold 300. A surface treatment may be performed on the surface of the mold 300 as an alternative to the coating layer 310. Surface treatments, such as using plasma, can be performed to reduce the surface energy of the mold 300. Therefore, when the second preliminary conductive layer 176 is formed on the surface of the mold 300 after the surface treatment on the surface of the mold 300, the cohesive force between the mold 300 and the second preliminary conductive layer 176 is reduced to allow the second preliminary conductive layer 176 to easily separate from the mold 300.

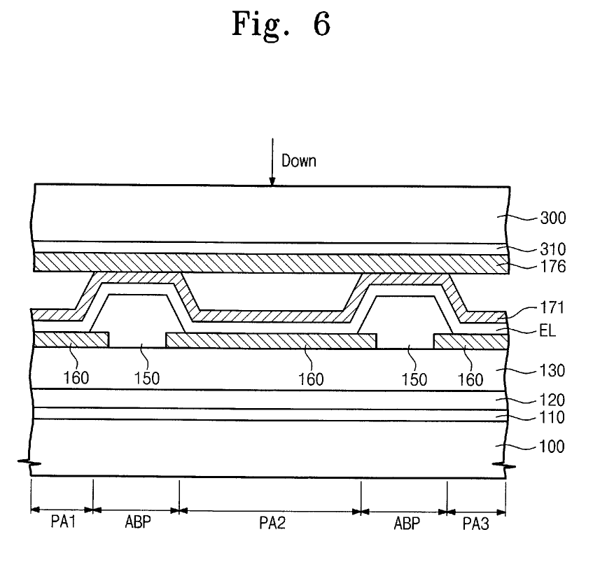

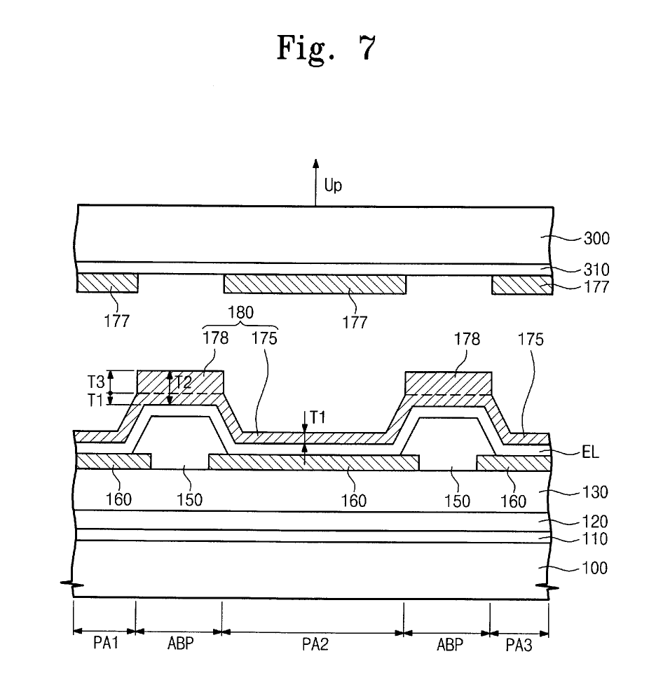

Referring to FIGS. 6 and 7, the first and second preliminary conductive layers 171 and 176 are heated to a temperature within a range that does not damage the organic light emitting layer EL, for instance a temperature of about 100° C. or below, while the mold 300 on which the second preliminary conductive layer 176 is formed is pressed onto the first preliminary conductive layer 171. Subsequently, a portion of the first preliminary conductive layer 171 formed in the peripheral area ABP makes contact with the second preliminary conductive layer 176 according to the spacing of the bank pattern 150.

When the first and second preliminary conductive layers 171 and 176 are heated and the second preliminary conductive layer 176 is pressed onto the first preliminary conductive layer 171, the second preliminary conductive layer 176 is transferred onto the first preliminary conductive layer 171 in areas where the first and second preliminary conductive layers 171 and 176 contact each other.

After the mold 300 on which the second preliminary conductive layer 176 is formed is pressed onto the substrate 100 on which the first preliminary conductive layer 171 is formed, the mold 300 is separated from the substrate 100. As a result, a portion of the second preliminary conductive layer 176 corresponding to the peripheral area ABP is transferred onto the first preliminary conductive layer 171 to complete the second electrode 180, including a first conductive layer 175 and a second conductive layer 178, on the organic light emitting layer EL, and a conductive layer pattern 177 remains on the mold 300.

When the second preliminary conductive layer 176 is entirely transferred onto the first preliminary conductive layer 171 in the peripheral area ABP, the second thickness T2 of the second electrode 180 in the peripheral area ABP is equal to a sum of the first thickness T1 (shown in FIG. 4) of the first preliminary conductive layer 171 and the third thickness T3 (shown in FIG. 5) of the second preliminary conductive layer 176. Although the second preliminary conductive layer 176 is only partially transferred onto the first preliminary conductive layer 171 in the peripheral area ABP, since the second electrode 180 is thicker in the peripheral area ABP than in the first to third pixel areas PA1, PA2, and PA3, the electrical resistance of the second electrode 180 may be reduced.

According to the above, the second electrode is formed by the imprint method to have different thicknesses in different regions. Thus, the amount of light emitted by the display device is maximized by forming a thin second electrode in the areas where the light exits. In addition, since the second electrode is thicker in the areas except for the areas where the light exits to the exterior, the electrical resistance of the second electrode may be reduced.

Although the exemplary embodiments of the present invention have been described, it is understood that the present invention should not be limited to these exemplary embodiments, but various changes and modifications can be made by one ordinary skilled in the art within the spirit and scope of the present invention as hereinafter claimed.

What is claimed is:

1. A method of manufacturing an organic light emitting display, comprising:
preparing a substrate having a plurality of pixel areas and a peripheral area surrounding each pixel area;
forming a first electrode on the substrate in each pixel area;
forming a bank pattern on the first electrode with an opening corresponding to each pixel area;
forming an organic light emitting layer in the opening; and
forming a second electrode on the organic light emitting layer,
wherein the forming of the second electrode comprises:
forming a first conductive layer on the organic light emitting layer; and
forming a second conductive layer on the first conductive layer by an imprint method.

2. The method of claim 1, wherein the forming of the second conductive layer by the imprint method comprises:
forming the second conductive layer on a surface of a mold; and
pressing the mold onto the substrate such that the first conductive layer makes contact with the second conductive layer, and transfers the second conductive layer onto the first conductive layer.

3. The method of claim 2, wherein, when the mold is pressed onto the substrate, the second conductive layer makes contact with a portion of the first conductive layer formed in the peripheral area corresponding to the spacing of the bank pattern.

4. The method of claim 3, wherein the first and second conductive layers are heated at a temperature of about 100° C. or below while the mold is pressed onto the substrate.

5. The method of claim 3, wherein the second electrode formed in the peripheral area is thicker than the second electrode formed in the pixel area.

6. The method of claim 1, wherein the second electrode comprises at least one of aluminum, silver, and magnesium.

7. The method of claim 6, wherein the first conductive layer and the second conductive layer comprise a same material.

8. The method of claim 1, wherein the organic light emitting layer overlaps at least two pixel areas adjacent to each other in a plan view.

9. The method of claim 1, wherein a light emitted from the organic light emitting layer exits through the second electrode.

10. The method of claim 2, wherein the forming of the second electrode further comprises:
forming a coating layer between the surface of the mold and the second conductive layer, and
wherein a cohesive force between the coating layer and the second conductive layer is weaker than a cohesive force between the surface of the mold and the second conductive layer.

11. The method of claim 10, wherein the coating layer comprises a teflon based material.

12. The method of claim 2, wherein the forming of the second electrode further comprises:
performing a surface treatment on the surface of the mold prior to forming the second conductive layer on the surface of the mold, and
wherein a surface energy of the mold is reduced by the surface treatment such that a cohesive force between the surface of the mold and the second conductive layer decreases.

13. The method of claim 2, wherein the mold comprises a flexible material.

14. An organic light emitting display comprising:
a substrate having a plurality of pixel areas and a peripheral area surrounding each pixel area;
a first electrode formed on the substrate in each pixel area;
a bank pattern formed on the first electrode and provided with an opening corresponding to each pixel area;
an organic light emitting layer filled in the opening and formed on the first electrode; and
a second electrode formed on the organic light emitting layer,
wherein the second electrode in the peripheral area is thicker than the second electrode in the pixel areas.

15. The organic light emitting display of claim 14, wherein the second electrode comprises:
a first conductive layer formed on an entire surface of the organic light emitting layer; and
a second conductive layer formed on the first conductive layer in the peripheral area.

16. The organic light emitting display of claim 15, wherein the second electrode comprises at least one of aluminum, silver, and magnesium.

17. The organic light emitting display of claim 16, wherein the first conductive layer and the second conductive layer comprise a same material.

18. The organic light emitting display of claim 14, wherein the organic light emitting layer overlaps at least two pixel areas formed adjacent to each other in a plan view.

19. The organic light emitting display of claim 14, wherein a light emitted from the organic light emitting layer exits through the second electrode.
